(19) United States
(12) Patent Application Publication
(10) Pub. No.: US 2023/0389280 A1
(43) Pub. Date: Nov. 30, 2023

(54) SEMICONDUCTOR DEVICE AND METHOD FOR FABRICATING THE SAME

(71) Applicant: SK hynix Inc., Gyeonggi-do (KR)

(72) Inventors: Jun Ha KWAK, Gyeonggi-do (KR); Seung Hwan KIM, Gyeonggi-do (KR)

(21) Appl. No.: 18/073,739

(22) Filed: Dec. 2, 2022

(30) Foreign Application Priority Data
May 30, 2022 (KR) 10-2022-0066132

(51) Int. Cl. H10B 12/00

(52) U.S. Cl. CPC H01L 27/10805; H01L 27/10873

(57) ABSTRACT

A method for fabricating a semiconductor device includes: forming a sacrificial pad including a plurality of line portions and a plurality of auxiliary lines over a lower structure; forming an etch target layer over the sacrificial pad; forming a plurality of openings by etching the etch-target layer and stopping the etching at the sacrificial pad; forming a pillar filling the openings; forming an isolation trench by etching the etch-target layer and stopping the etching at the sacrificial pad; and forming a pad-type recess by removing the sacrificial pad through the isolation trench.

### CROSS-REFERENCE TO RELATED APPLICATIONS

The present application claims priority of Korean Patent Application No. 10-2022-0066132, filed on May 30, 2022, which is incorporated herein by reference in its entirety.

### BACKGROUND

### 1. Field

The present invention relates generally to a semiconductor device, and more particularly, to a semiconductor device including three-dimensional memory cells, and a method for fabricating the semiconductor device.

### 2. Description of the Related Art

The size of a memory cell is being continuously reduced to increase the net die of a memory device. As the size of memory cells is miniaturized, it is required to reduce parasitic capacitance Cb and increase capacitance as well. However, it is difficult to increase the net die due to the structural limitation of memory cells.

Recently, three-dimensional semiconductor memory devices including memory cells that are arranged in three dimensions are being suggested.

### SUMMARY

Embodiments of the present invention are directed to a semiconductor device including highly integrated memory cells and a method for fabricating the same.

In accordance with an embodiment of the present invention, a method for fabricating a semiconductor device includes: forming a sacrificial pad including a plurality of line portions and a plurality of auxiliary lines over a lower structure; forming an etch target layer over the sacrificial pad; forming a plurality of openings by etching the etch-target layer and stopping the etching at the sacrificial pad; forming a slit filling the openings; forming an isolation trench by etching the etch-target layer and stopping the etching at the sacrificial pad; and forming a pad-type recess by removing the sacrificial pad through the isolation trench.

In accordance with another embodiment of the present invention, a semiconductor device includes: a dielectric pad over a lower structure, the contact portion positioned at a higher level than the dielectric pad and including a first word line stack pad and a second word line stack pad; and a slit structure including a plurality of slits extending vertically from the dielectric pad to support the first word line stack pad and the second word line stack pad.

### BRIEF DESCRIPTION OF THE DRAWINGS

FIGS. 1A to 1F are plan views illustrating a method for fabricating a semiconductor device in accordance with an embodiment of the present invention.

FIGS. 2A to 2F are cross-sectional views taken along a line A-A′ shown in FIGS. 1A to 1F illustrating the fabrication method.

FIG. 3 is a schematic perspective view illustrating a semiconductor device in accordance with embodiments of the present invention.

FIG. 4 is a schematic cross-sectional view illustrating a memory cell shown in FIG. 3.

FIG. 5 is a side schematic perspective view illustrating a semiconductor device in accordance with embodiments of the present invention.

FIG. 6 is a schematic cross-sectional view illustrating a word line stack shown in FIG. 5.

FIG. 7A is a schematic plan view illustrating a semiconductor device in accordance with other embodiments of the present invention.

FIG. 7B is a detailed layout view illustrating a cell array portion shown in FIG. 7A.

FIG. 8 is a cross-sectional view taken along a line A-A′ shown in FIG. 7A.

FIG. 9 is a cross-sectional view taken along a line B-B′ shown in FIG. 7A.

FIG. 10 is a cross-sectional view taken along a line C-C′ shown in FIG. 7A.

FIG. 11 is a schematic plan view illustrating a sacrificial pad of a semiconductor device in accordance with another embodiment of the present invention.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

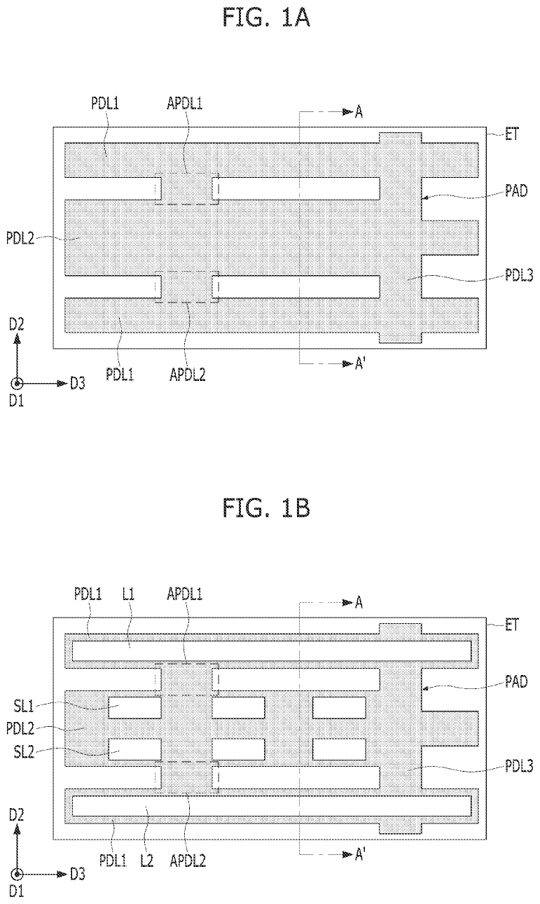

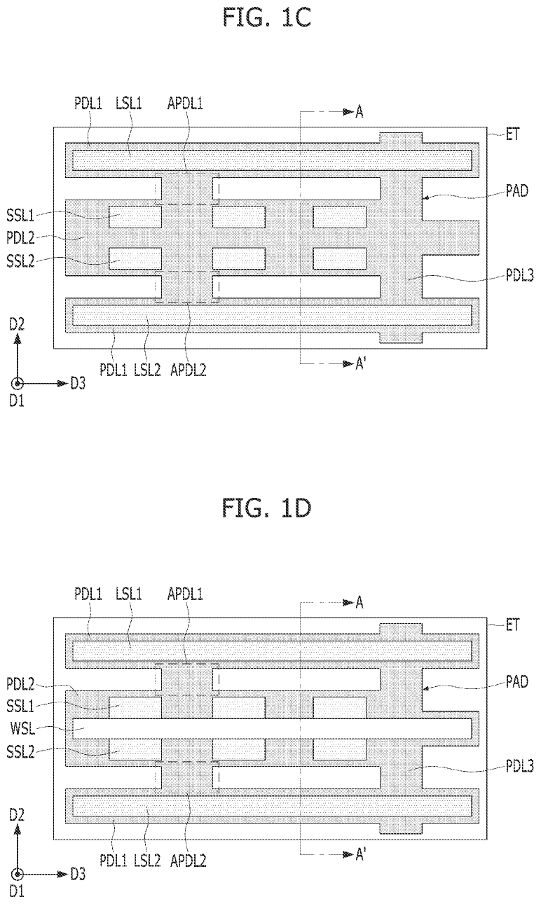

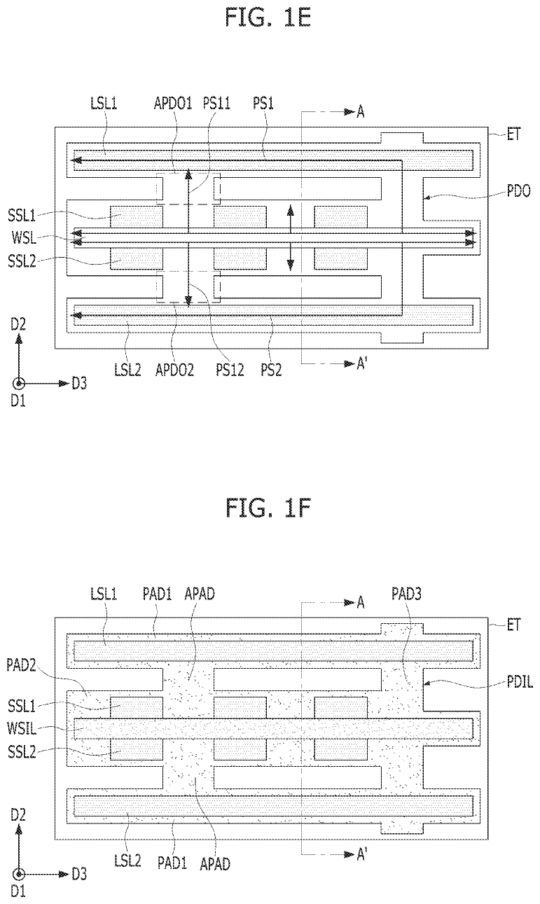

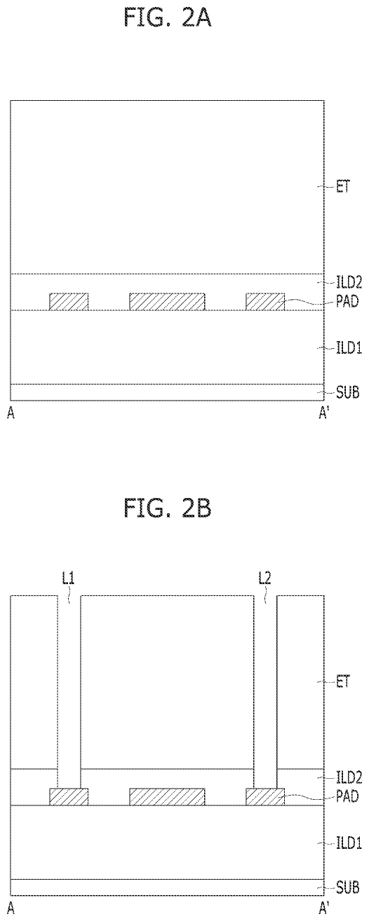

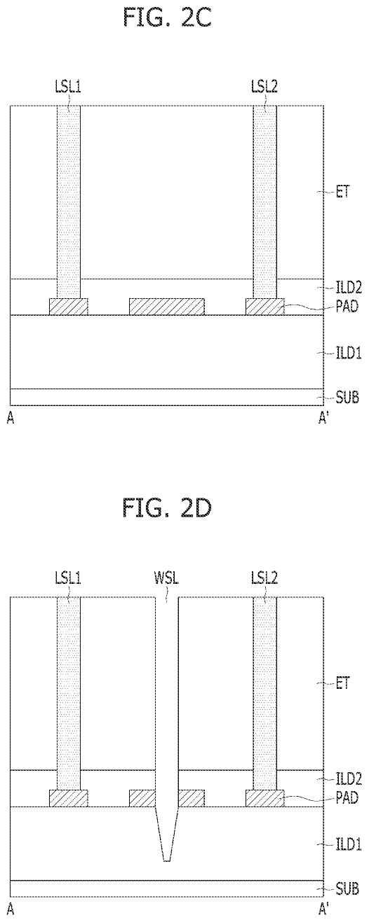

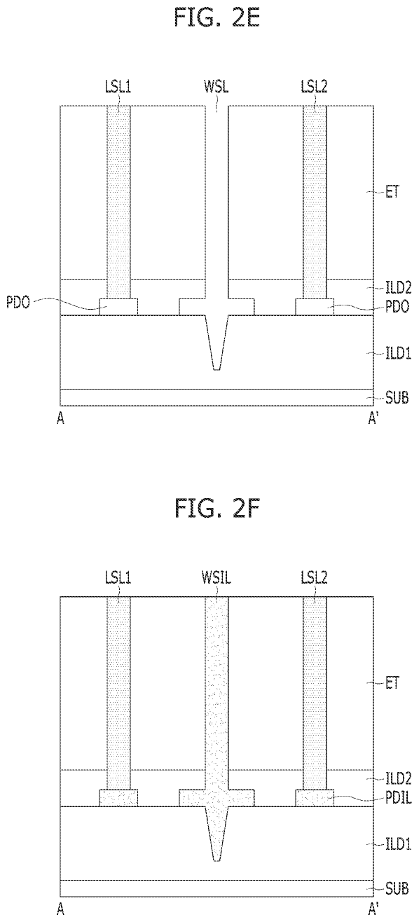

FIGS. 1A to 1F are plan views illustrating a method for fabricating a semiconductor device in accordance with an embodiment of the present invention. FIGS. 2A to 2F are cross-sectional views taken along a line A-A′ shown in FIGS. 1A to 1F illustrating the fabrication method.

Referring to FIGS. 1A and 2A, a first inter-layer dielectric layer ILD1 may be formed over a lower structure SUB, and a sacrificial pad PAD may be formed over the first inter-layer dielectric layer ILD1. A second inter-layer dielectric layer ILD2 may be formed over the sacrificial pad PAD. The first inter-layer dielectric layer ILD1, the sacrificial pad PAD, and the second inter-layer dielectric layer ILD2 may be sequentially formed in a first direction D1 which is perpendicular to the surface of the lower structure SUB.

The first and second inter-layer dielectric layers ILD1 and ILD2 may include a dielectric material. For example, the first and second inter-layer dielectric layers ILD1 and ILD2 may include silicon oxide, silicon nitride, a low-k material, or a combination thereof. The sacrificial pad PAD may include a metal-based material. The sacrificial pad PAD may include, for example, titanium nitride, tungsten, or a combination thereof. The sacrificial pad PAD may include a ‘TiN/W stack’ in which titanium nitride and tungsten are stacked in the mentioned order. The sacrificial pad PAD may serve as an etch stopper during a subsequent etching process.

When viewed from the perspective of a top view, the sacrificial pad PAD may have a mesh-shape or a lattice-shape. The sacrificial pad PAD may include a plurality of line portions PDL1, PDL2 and PDL3 and a plurality of auxiliary lines APDL1 and APDL2. The line portions PDL1, PDL2, and PDL3 may include a first line portion PDL1, a second line portion PDL2, and a third line portion PDL3. The auxiliary lines APDL1 and APDL2 may include a first auxiliary line APDL1 and a second auxiliary line APDL2. The first and second line portions PDL1 and PDL2 may extend in a third direction D3, and the third line portion PDL3 may extend in a second direction D2. The second direction D2 and the third direction D3 may intersect with each other. The first and second auxiliary lines APDL1 and APDL2 may be positioned between the first line portion PDL1 and the second line portion PDL2. The first and second auxiliary lines APDL1 and APDL2 may interconnect the first line portion PDL1 and the second line portion PDL2 to each other. The first line portion PDL1, the second line portion PDL2, the third line portion PDL3, the first auxiliary line APDL1, and the second auxiliary line APDL2 may have an integrated structure. The first line portion PDL1, the second line portion PDL2, the third line portion PDL3, the first auxiliary line APDL1, and the second auxiliary line APDL2 may be formed of the same material. The first line portion PDL1, the second line portion PDL2, the third line portion PDL3, the first auxiliary line APDL1, and the second auxiliary line APDL2 may be positioned at the same lateral level. According to an embodiment of the present invention, one first auxiliary line APDL1 is taken as an example, but according to another embodiment of the present invention, a plurality of the first auxiliary lines APDL1 may be positioned between the first line portion PDL1 and the second line portion PDL2 in the third direction D3. Also, a plurality of the second auxiliary lines APDL2 may be positioned between the first line portion PDL1 and the second line portion PDL2 in the third direction D3.

Subsequently, an etch target layer ET may be formed over the second inter-layer dielectric layer ILD2. The etch target layer ET may include a dielectric material, a semiconductor material, an oxide semiconductor material, a metal material, or a combination thereof. For example, the etch target layer ET may include silicon oxide, silicon nitride, polysilicon, IGZO, or a stack thereof. According to an embodiment of the present invention, the etch target layer ET may be formed by stacking a first silicon oxide, a first silicon nitride, polysilicon, a second silicon nitride, and a second silicon oxide in the mentioned order.

According to another embodiment of the present invention, the etch target layer ET may include an alternating stack in which different materials are alternately stacked, and a sacrificial pad PAD may include a material having an etch selectivity with respect to the alternating stack.

According to another embodiment of the present invention, the etch target layer ET may include a dielectric layer, a semiconductor layer, or a combination thereof.

According to another embodiment of the present invention, the etch target layer ET may include an alternating stack in which dielectric layers and semiconductor layers are alternately stacked.

According to another embodiment of the present invention, the etch target layer ET may include at least one stack layer in which a first dielectric layer, a second dielectric layer, a semiconductor layer, and a third dielectric layer are stacked in the mentioned order, wherein the first dielectric layer may include silicon oxide, and the second and third dielectric layers may include silicon nitride, and the semiconductor layer may include polysilicon. The etch target layer ET may include an ONPN (oxide-nitride-polysilicon-nitride) stack.

The etch target layer ET may include an alternating stack in which the first semiconductor layers and the second semiconductor layers are alternately stacked, wherein the first semiconductor layers include monocrystalline silicon or polysilicon, and the second semiconductor layers include silicon germanium.

Referring to FIGS. 1B and 2B, a plurality of openings L1, L2, SL1, and SL2 may be formed in the etch target layer ET. To form the openings L1, L2, SL1, and SL2, the etch target layer ET and the second inter-layer dielectric layer ILD2 may be sequentially etched. The etching process for forming the openings L1, L2, SL1, and SL2 may include dry etching, wet etching, or a combination thereof. The openings L1, L2, SL1, and SL2 may include large openings L1 and L2 and small openings SL1 and SL2. The large openings L1 and L2 may be larger than the small openings SL1 and SL2. The large openings L1 and L2 may extend laterally in the third direction D3 and vertically extend in the first direction D1. The small openings SL1 and SL2 may extend vertically in the first direction D1. The small openings SL1 and SL2 may be regularly positioned in the third direction D3. The etching process for forming the large openings L1 and L2 may stop at the first line portions PDL1 of the sacrificial pad PAD. The etching process for forming the small openings SL1 and SL2 may stop at the second line portions PDL2 of the sacrificial pad PAD. The large openings L1 and L2 and the small openings SL1 and SL2 may not be formed over the third line portions PDL3 and the first and second auxiliary lines APDL1 and APDL2 of the sacrificial pad PAD.

Referring to FIGS. 1C and 2C, slits LSL1, LSL2, SSL1, P and SSL2 may be formed by filling the large openings L1 and L2 and the small openings SL1 and SL2, respectively. The large openings L1 and L2 may be filled to form the large slits LSL1 and LSL2, and the small openings SL1 and SL2 may be filled to form the small slits SSL1 and SSL2. The large slits LSL1 and LSL2 and the small slits SSL1 and SSL2 may include a dielectric material. For example, the large slits LSL1 and LSL2 and the small slits SSL1 and SSL2 may include silicon oxide, silicon carbon oxide, silicon nitride, a low-k material, or a combination thereof. The large slits LSL1 and LSL2 may extend laterally in the third direction D3 and may extend vertically in the first direction D1. The small slits SSL1 and SSL2 may extend vertically in the first direction D1. The small slits SSL1 and SSL2 may be regularly positioned in the third direction D3.

Referring to FIGS. 1D and 2D, an isolation trench WSL may be formed between the small slits SSL1 and SSL2. The isolation trench WSL may extend laterally in the third direction D3. The etch target layer ET and the second inter-layer dielectric layer ILD2 may be sequentially etched to form the isolation trench WSL. The isolation trench WSL may be formed between the small slits SSL1 and SSL2 that are positioned adjacent to each other in the second direction D2.

As described above, since the sacrificial pad PAD is used as an etch stopper during the etching process for forming the large openings L1 and L2, the small openings SL1 and SL2, and the isolation trench WSL, it is possible to prevent arcing during the etching process of the etch target layer ET, thus improving the reliability of the semiconductor device.

Also, since the sacrificial pad PAD of the metal-based material is formed below the etch target layer ET, charges induced during a plasma etching process of the etch target layer ET may be discharged to the lower structure SUB.

Referring to FIGS. 1E and 2E, the sacrificial pad PAD may be stripped through the isolation trench WSL. As the sacrificial pad PAD is stripped, a pad-shaped recess PDO may be formed. The first line portions PDL1, the second line portions PDL2, the third line portion PDL3, and the first and second auxiliary lines APDL1 and APDL2 of the sacrificial pad PAD may be all removed to form the pad-shaped recess PDO. The pad-shaped recess PDO may include auxiliary pad-shaped recesses APDO1 and APDO2 that are defined in a space from which the first and second auxiliary lines APDL1 and APDL2 are removed.

In order to remove the sacrificial pad PAD, a wet etching process using a wet chemical may be performed. The wet chemical may flow in through the isolation trench WSL, for example, through a plurality of paths PS1, PS2, PS11, and PS12. The first line portion PDL1, the second line portion PDL2, the third line portion PDL3, and the first and second auxiliary lines APDL1 and APDL2 may be stripped by the wet chemical.

The paths PS1, PS2, PS11, and PS12 through which the wet chemical flows in may include a first path group PS1 and PS2 and a second path group PS11 and PS12. The first path group PS1 and PS2 may be paths for removing the first line portion PDL1, the second line portion PDL2, and the third line portion PDL3. The second path group PS11 and PS12 may be paths for removing the first and second auxiliary lines APDL1 and APDL2.

As described above, since the path for stripping the sacrificial pad PAD includes the first path group PS1 and PS2 and the second path group PS11 and PS12, the sacrificial pad PAD may be removed without any residue. In particular, the sacrificial pad PAD may be more easily removed by the second path group PS11 and PS12.

As a comparative example, when the second path group PS11 and PS12 is omitted, that is, when the sacrificial pad PAD does not include the first and second auxiliary lines APDL1 and APDL2, the wet chemical may not flow in sufficiently. Therefore, a portion of the sacrificial pad PAD may remain.

Subsequently, an isolation slit WSIL filling the isolation trench may be formed, as illustrated in FIGS. 1F and 2F. While the isolation slit WSIL is being formed, a dielectric pad PDIL filling the pad-shaped recess PDO may be formed. The isolation slit WSIL and the dielectric pad PDIL may include silicon oxide, silicon carbon oxide, silicon nitride, or a combination thereof. The dielectric pad PDIL may be referred to as a lateral dielectric pad.

The dielectric pad PDIL may include a plurality of line pads PAD1, PAD2, and PAD3 and a plurality of auxiliary pads APAD. The line pads PAD1, PAD2, and PAD3 may include a first line pad PAD1, a second line pad PAD2, and a third line pad PAD3. The first and second line pads PAD1 and PAD2 may extend in the third direction D3, and the third line pad PAD3 may extend in the second direction D2. The first line pad PAD1 and the second line pad PAD2 may be parallel to each other. The second direction D2 and the third direction D3 intersect with each other. The auxiliary pads APAD may be positioned between the first line pad PAD1 and the second line pad PAD2. The auxiliary pad APAD may interconnect the first line pad PAD1 and the second line pad PAD2 to each other. The first line pad PAD1, the second line pad PAD2, the third line pad PAD3, and the auxiliary pads APAD may have an integrated structure. The first line pad PAD1, the second line pad PAD2, the third line pad PAD3, and the auxiliary pads APAD may be formed of the same material. The first line pad PAD1, the second line pad PAD2, the third line pad PAD3, and the auxiliary pads APAD may be positioned at the same lateral level.

According to the following embodiments of the present invention, it is possible to increase the memory cell density and reduce parasitic capacitance by vertically stacking memory cells.

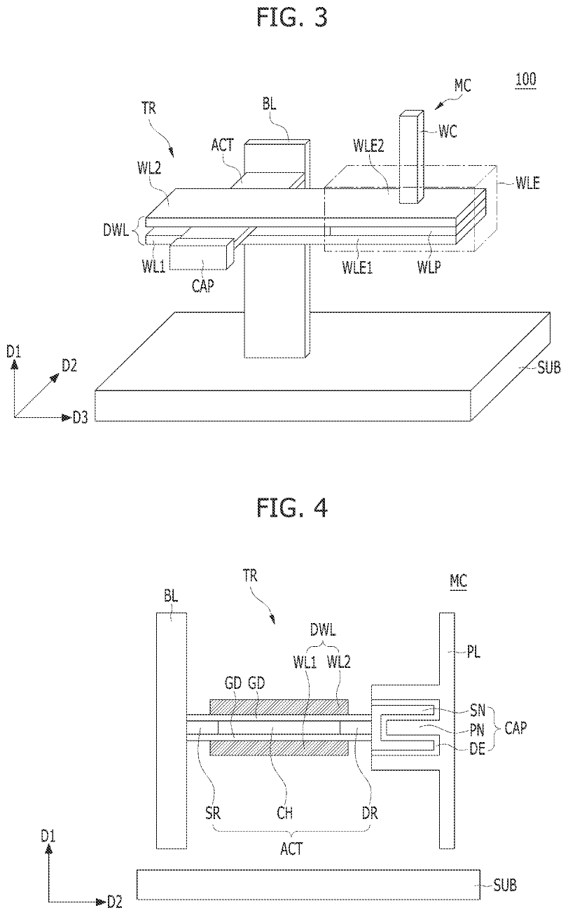

FIG. 3 is a schematic perspective view illustrating a semiconductor device in accordance with embodiments of the present invention. FIG. 4 is a schematic cross-sectional view illustrating a memory cell shown in FIG. 3.

Referring to FIG. 3, the semiconductor device 100 may include a lower structure SUB, a conductive line stack DWL including a pair of lateral conductive lines WL1 and WL2 that are disposed over the lower structure SUB, a conductive pad WLP interposed between the pad portions WLE1 and WLE2 of the lateral conductive lines WL1 and WL2, a contact plug WC contacting the pad portion WLE of the conductive line stack DWL, a vertical conductive line BL extending in a direction perpendicular to the surface of the lower structure SUB over the lower structure SUB, and a lateral layer ACT oriented laterally in a direction intersecting with the lateral conductive lines WL1 and WL2. The pair of the lateral conductive lines WL1 and WL2 may include a first lateral conductive line WL1 and a second lateral conductive line WL2. The pad portions WLE1 and WLE2 of the lateral conductive lines WL1 and WL2 may include a first lateral conductive line pad portion WLE1 and a second lateral conductive line pad portion WLE2. The first lateral conductive line WL1 may include a first lateral conductive line pad portion WLE1, and the second lateral conductive line WL2 may include a second lateral conductive line pad portion WLE2. The contact plug WC may be coupled to the second lateral conductive line pad portion WLE2. The first lateral conductive line WL1 may be positioned on an upper surface of the lateral layer ACT, and the second lateral conductive line WL2 may be positioned on a lower surface of the lateral layer ACT. The conductive pad WLP may electrically connect the first lateral conductive line pad portion WLE1 and the second lateral conductive line pad portion WLE2 to each other. The conductive pad WLP may also be referred to as an assistant pad, a connection pad, or a buffer pad.

The semiconductor device 100 may include a memory cell MC, and the memory cell MC may include a memory cell of a memory device, such as Dynamic Random Access Memory (DRAM). The lateral conductive lines WL1 and WL2 may be simply referred to as first and second word lines WL1 and WL2, and the vertical conductive line BL may be simply referred to as a bit line BL. The conductive line stack DWL may be simply referred to as a word line DWL, and the conductive pad WLP may be simply referred to as a word line pad WLP. The lateral layer ACT may be simply referred to as the active layer ACT. The word line DWL may include a pair of word lines, that is, a pair of a first word line WL1 and a second word line WL2. The first word line WL1 and the second word line WL2 may be oriented laterally in the third direction D3 with the active layer ACT interposed therebetween. The first word line WL1 and the second word line WL2 may be vertically stacked in the first direction D1 with the active layer ACT interposed therebetween.

Referring to FIGS. 3 and 4, the semiconductor device 100 may include a lower structure SUB and a memory cell MC. The memory cell MC may be positioned at a higher level than the lower structure SUB. The memory cell MC may include a bit line BL, a transistor TR, and a capacitor CAP. The transistor TR may include an active layer ACT and a word line DWL, wherein the word line DWL may include a first word line WL1 and a second word line WL2 that are facing opposite to each other with the active layer ACT interposed therebetween. The capacitor CAP may include a storage node SN, a dielectric layer DE, and a plate node PN. The capacitor CAP may be an example of a data storage element, and the data storage element may be replaced with a memory element other than the capacitor CAP.

The bit line BL may extend in a first direction D1 which is perpendicular to the surface of the lower structure SUB. The active layer ACT may extend in a second direction D2 which is parallel to the surface of the lower structure SUB. The word line DWL may extend in a third direction D3 which is parallel to the surface of the lower structure SUB, and the third direction D3 may intersect with the first and second directions D1 and D2.

The bit line BL may be vertically oriented in the first direction D1. The bit line BL may be referred to as a vertically oriented bit line or a pillar-type bit line. The bit line BL may include a conductive material. The bit line BL may include a silicon-based material, a metal-based material, or a combination thereof. The bit line BL may include silicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include, for example, titanium nitride and tungsten. For example, the bit line BL may include a TiN/W stack including titanium nitride and tungsten over titanium nitride.

The word line DWL may extend in the third direction D3, and the active layer ACT may extend in the second direction D2. The active layer ACT may be laterally arranged in the second direction D2 from the bit line BL. The word line DWL may have a double word line structure. In other words, the word line DWL may include a first word line WL1 and a second word line WL2. The first word line WL1 and the second word line WL2 may face each other in the first direction D1 with the active layer ACT interposed therebetween.

The active layer ACT may laterally oriented between the bit line BL and the capacitor CAP. A first end of the active layer ACT may be coupled to the bit line BL, and a second end of the active layer ACT may be coupled to the capacitor CAP. The active layer ACT may include a semiconductor material or an oxide semiconductor material. For example, the active layer ACT may include silicon, monocrystalline silicon, germanium, silicon germanium, or indium gallium zinc oxide (IGZO).

The active layer ACT may include a channel CH, a first source/drain region SR between the channel CH and the bit line BL, and a second source/drain region DR between the channel CH and the capacitor CAP. The channel CH may be defined between the first source/drain region SR and the second source/drain region DR. The channel CH and the word line DWL may vertically overlap with each other in the first direction D1. The channel CH may extend laterally in the second direction D2.

The first source/drain region SR and the second source/drain region DR may be doped with impurities of the same conductivity type. The first source/drain region SR and the second source/drain region DR may be doped with an N-type impurity or a P-type impurity. The first source/drain region SR and the second source/drain region DR may include at least one impurity selected among arsenic (As), phosphorus (P), boron (B), indium (In), and a combination thereof. The first source/drain region SR may contact the bit line BL, and the second source/drain region DR may contact the storage node SN of the capacitor CAP.

The transistor TR may be a cell transistor and it may have a word line DWL. In the word line DWL, the first word line WL1 and the second word line WL2 may have the same potential. For example, the first word line WL1 and the second word line WL2 may form a pair, and the same word line driving voltage may be applied to the first word line WL1 and the second word line WL2. The first word line WL1 and the second word line WL2 may be interconnected by a word line pad WLP, and the same word line driving voltage may be applied by a contact plug WC.

As described, the memory cell MC according to an embodiment of the present invention may have a word line DWL of a double word line structure in which a first word line WL1 and a second word line WL2 are disposed adjacent to one channel CH.

The active layer ACT may have a smaller thickness than those of the first and second word lines WL1 and WL2. In other words, the vertical thickness of the active layer ACT in the first direction D1 may be smaller than the vertical thickness of each of the first and second word lines WL1 and WL2 in the first direction D1. Such a thin active layer ACT may be referred to as a thin-body active layer. The thin active layer ACT may include a thin-body channel CH, and the thin-body channel CH may have a thickness of approximately 10 nm or less. According to another embodiment of the present invention, the channel CH may have the same vertical thickness as those of the first and second word lines WL1 and WL2.

The upper and lower surfaces of the active layer ACT may have a flat surface. In other words, the upper surface and the lower surface of the active layer ACT may be parallel to each other in the second direction D2.

A gate dielectric layer GD may be formed between each of the first and second word lines WL1 and WL2 and the active layer ACT. The gate dielectric layer GD may include silicon oxide, silicon nitride, a metal oxide, a metal oxynitride, a metal silicate, a high-k material, a ferroelectric material, an anti-ferroelectric material or a combination thereof. The gate dielectric layer GD may include SiO₂, Si₃N₄, HfO₂, Al₂O₃, ZrO₂, AlON, HfON, HfSiO, HfSiON, or HfZrO.

Each of the first and second word lines WL1 and WL2 may include a metal, a metal mixture, a metal alloy, or a semiconductor material. Each of the first and second word lines WL1 and WL2 may include, for example, titanium nitride, tungsten, polysilicon, or a combination thereof. For example, each of the first and second word lines WL1 and WL2 may include a TiN/W stack in which titanium nitride and tungsten are sequentially stacked. Each of the first and second word lines WL1 and WL2 may include an N-type work function material or a P-type work function material. The N-type work function material may have a low work function of approximately 4.5 eV or less, and the P-type work function material may have a high work function of approximately 4.5 eV or more.

The capacitor CAP may be positioned laterally from the transistor TR in the second direction D2. The capacitor CAP may include a storage node SN that extends laterally from the active layer ACT in the second direction D2. The capacitor CAP may further include a dielectric layer DE and a plate node PN over the storage node SN. The storage node SN, the dielectric layer DE, and the plate node PN may be arranged laterally in the second direction D2. The storage node SN may have a laterally oriented cylinder shape. The dielectric layer DE may conformally cover the cylindrical inner wall and the cylindrical outer wall of the storage node SN. The plate node PN may have a shape extending to the cylindrical inner wall and the cylindrical outer wall of the storage node SN over the dielectric layer DE. The storage node SN may be electrically connected to the second source/drain region DR. The plate node PN may be coupled to the plate line PL. The plate node PN and the plate line PL may be of the same material and they may have an integrated structure.

The storage node SN may have a three-dimensional structure. The storage node SN may have a lateral three-dimensional structure which is oriented in the second direction D2. For example, the storage node SN may have a cylinder shape. According to other examples, the storage node SN may have a pillar shape or a pylinder shape. The pylinder shape may refer to a structure in which a pillar shape and a cylinder shape are merged.

The storage node SN and the plate node PN may include a metal, a noble metal, a metal nitride, a conductive metal oxide, a conductive noble metal oxide, a metal carbide, a metal silicide, or a combination thereof. For example, the storage node SN and the plate node PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack. The plate node PN may include a combination of a metal-based material and a silicon-based material. For example, the plate node PN may be a stack of titanium nitride/silicon germanium/tungsten nitride (TiN/SiGe/WN). In the TiN/SiGe/WN stack, the silicon germanium (SiGe) may be a gap-fill material filling the cylindrical inside of the storage node SN over the titanium nitride (TiN), and the titanium nitride may serve as a plate node PN of the capacitor CAP, and the tungsten nitride (WN) may be a low-resistance material.

The dielectric layer DE may include silicon oxide, silicon nitride, a high-k material, or a combination thereof. The high-k material may have a higher dielectric constant than silicon oxide (SiO₂). Silicon oxide may have a dielectric constant of approximately 3.9. The dielectric layer DE may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including at least zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including at least hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, the aluminum oxide (Al₂O₃) may have a greater bandgap energy (which will be, hereinafter, simply referred to as bandgap) than zirconium oxide (ZrO₂) and hafnium oxide (HfO₂). Aluminum oxide (Al₂O₃) has a lower dielectric constant than zirconium oxide (ZrO₂) and hafnium oxide (HfO₂). Accordingly, the dielectric layer DE may include a stack of a high-k material and a high-bandgap material having a greater bandgap than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material.

According to another embodiment of the present invention, the dielectric layer DE may include a laminated structure in which a high-k material and a high-bandgap material are alternately stacked. For example, it may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the dielectric layer DE may include a stack structure, a laminated structure, or a mixed structure including zirconium oxide, hafnium oxide, and aluminum oxide.

According to another embodiment of the present invention, the dielectric layer DE may include a ferroelectric material or an antiferroelectric material.

According to another embodiment of the present invention, an interface control layer for improving leakage current may be further formed between the storage node SN and the dielectric layer DE. The interface control layer may include titanium oxide (TiO₂), niobium oxide, or niobium nitride. The interface control layer may also be formed between the plate node PN and the dielectric layer DE.

The capacitor CAP may include a metal-insulator-metal (MIM) capacitor. The storage node SN and the plate node PN may include a metal-based material.

The capacitor CAP may be replaced with another data storage material. For example, the data storage material may be a phase change material, a magnetic tunnel junction (MTJ), or a variable resistance material.

Referring back to FIG. 3, the word line DWL may include a word line pad portion WLE. A contact plug WC may be coupled to the word line pad portion WLE. The word line pad portion WLE may refer to the end portion of the word line DWL, that is, end portions of the first and second word lines WL1 and WL2. For example, the word line pad portion WLE may include a first word line pad portion WLE1 and a second word line pad portion WLE2. The word line pad portion WLE may further include a word line pad WLP between the first word line pad portion WLE1 and the second word line pad portion WLE2. The first word line pad portion WLE1 and the second word line pad portion WLE2 may be electrically connected to each other by the word line pad WLP. The word line pad WLP may also be referred to as a ‘connection pad WLP’.

The word line pad WLP may be laterally spaced apart from the active layer ACT. The word line pad WLP may directly contact the first word line pad portion WLE1 and the second word line pad portion WLE2. The first word line pad portion WLE1, the word line pad WLP, and the second word line pad portion WLE2 may be vertically stacked in the first direction D1. An end portion of the word line pad portion WLE may include a vertical flat surface. Accordingly, the end of the word line pad WLP may be self-aligned with the end of the first word line pad portion WLE1 and the end of the second word line pad portion WLE2.

The first word line pad portion WLE1 and the second word line pad portion WLE2 may be formed of the same material. Each of the first and second word line pad portions WLE1 and WLE2 may include a metal, a metal mixture, a metal alloy, or a semiconductor material. Each of the first and second word line pad portions WLE1 and WLE2 may include, for example, titanium nitride, tungsten, polysilicon, or a combination thereof. For example, each of the first and second word line pad portions WLE1 and WLE2 may include a TiN/W stack in which titanium nitride and tungsten are sequentially stacked.

The word line pad WLP may be formed of the same material as those of the first and second word line pad portions WLE1 and WLE2. The word line pad WLP may include a metal, a metal mixture, a metal alloy, or a semiconductor material. The word line pad WLP may include, for example, titanium nitride, tungsten, polysilicon, or a combination thereof. For example, the word line pad WLP may include a TiN/W stack in which titanium nitride and tungsten are sequentially stacked. The first word line pad portion WLE1 and the second word line pad portion WLE2 may be electrically connected to each other by the word line pad WLP.

The contact plug WC may extend vertically in the first direction D1. The contact plug WC may be directly coupled to the second word line pad portion WLE2. The contact plug WC may include a metal-based material.

The first and second word line pad portions WLE1 and WLE2 may be supported by an isolation slit WSIL, large slits LSL1 and LSL2, and small slits SSL1 and SSL2, which are illustrated in FIGS. 1A to 2F.

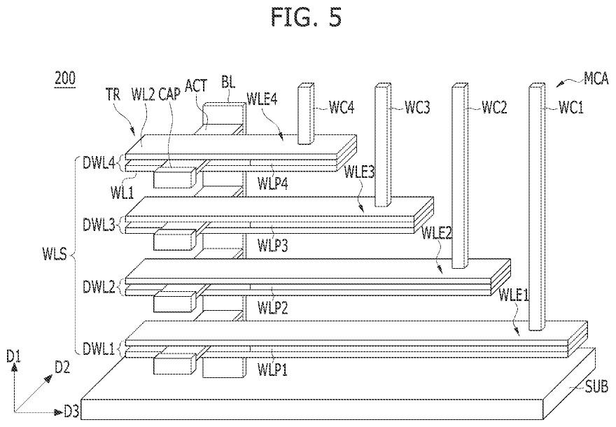

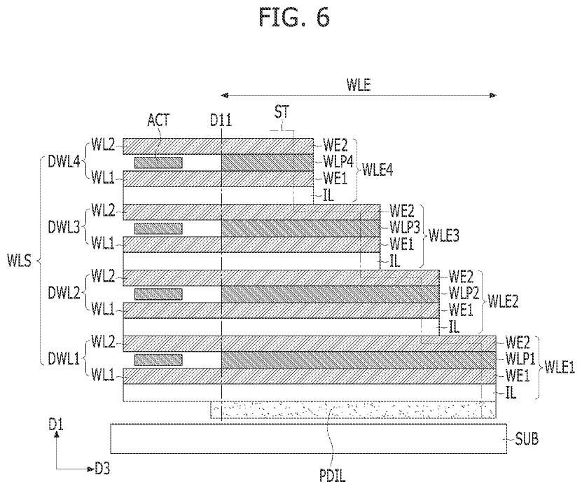

FIG. 5 is a schematic perspective view illustrating a semiconductor device in accordance with embodiments of the present invention. FIG. 6 is a schematic side cross-sectional view illustrating a word line stack WLS shown in FIG. 5.

Referring to FIGS. 5 and 6, the semiconductor device 200 may include a memory cell array MCA. The memory cell array MCA may include a plurality of memory cells. Herein, the memory cells of the memory cell array MCA may include the memory cells MC shown in FIGS. 3 and 4. The memory cells MC shown in FIGS. 3 and 4 may be vertically stacked in the first direction D1 as illustrated in FIG. 3.

The memory cell array MCA may include a plurality of active layers ACT and a plurality of word lines DWL1 to DWL4 that are vertically stacked over a lower structure SUB. Each of the word lines DWL1 to DWL4 may include first and second word lines WL1 and WL2 that are facing each other with an active layer ACT interposed therebetween. The word lines DWL1 to DWL4 may be vertically stacked in the first direction D1 over the surface of the lower structure SUB. The stack of the word lines DWL1 to DWL4 may be simply referred to as a ‘word line stack WLS’.

The memory cell array MCA may further include a bit line BL, a plurality of transistors TR, and a plurality of capacitors CAP over the lower structure SUB. Each of the transistors TR may include an active layer ACT and a word line DWL1 to DWL4. The word lines DWL1 to DWL4 may extend laterally in the third direction D3.

The word line stack WLS may include a word line pad portion WLE, and the word line pad portion WLE may include word line pad portions WLE1 to WLE4. The word line pad portions WLE1 to WLE4 may refer to the end portions of the word lines DWL1 to DWL4. The word line pad portions WLE1 to WLE4 may form a stepped structure. Contact plugs WC1 to WC4 may be respectively coupled to the word line pad portions WLE1 to WLE4. Each of the word line pad portions WLE1 to WLE4 may refer to the end portions of the first and second word lines WL1 and WL2. Each of the word line pad portions WLE1 to WLE4 may include a first pad WE1 and a second pad WE2 (See FIG. 6). The word line pad portions WLE1 to WLE4 may further include word line pads WLP1 to WLP4, respectively. The word line pads WLP1 to WLP4 may be laterally spaced apart from the active layers ACT. Each of the word line pads WLP1 to WLP4 may be formed between the first pad WE1 and the second pad WE2. The word line pads WLP1 to WLP4 may directly contact the first and second pads WE1 and WE2.

First ends of the word line pad portions WLE1 to WLE4 may be aligned at a vertical level D11. First ends of the word line pads WLP1 to WLP4 may be aligned at the vertical level D11. In each of the word line pads WLP1 to WLP4, second ends of the word line pads WLP1 to WLP4 may be self-aligned with the ends of the first and second pads WE1 and WE2.

The word line pad portion WLE of the word line stack WLS may have a step shape (refer to ‘ST’). The second ends of the word line pad portions WLE1 to WLE4 may not be aligned with each other. For example, the second ends of the word line pad portions WLE1 to WLE4 may not be aligned with each other along the step shape ST.

The word line pads WLP1 to WLP4 may extend laterally in the third direction D3. The word line pads WLP1 to WLP4 may have different lengths in the lateral direction. The lengths of the word line pads WLP1 to WLP4 in the lateral direction may gradually decrease as it goes from the lowermost word line pad WLP1 toward the uppermost word line pad WLP4.

A conductive line having a ‘D’ shape may be formed by combining the individual double word lines DWL1 to DWL4 and the individual word line pads WLP1 to WLP4.

A method for forming the word line pads WLP1 to WLP4 may include forming a pad-shaped recess by removing the materials (e.g., a dielectric material, a semiconductor material) positioned between the first pad WE1 and the second pad WE2 and filling the pad-shaped recess with a conductive material. The word line pads WLP1 to WLP4 may be defined at the ends of the word lines DWL1 to DWL4 while the word lines DWL1 to DWL4 are formed.

The word line stack WLS may further include cell isolation layers IL, and the cell isolation layers IL may be positioned between the word line pad portions WLE1 to WLE4. The cell isolation layers IL may extend laterally to be positioned between the word lines DWL1 to DWL4. The cell isolation layers IL may extend laterally in the third direction D3. The cell isolation layers IL may have different lengths in the lateral direction. The lateral direction lengths of the cell isolation layers IL may gradually decrease as it goes from the lowermost cell isolation layer IL toward the uppermost cell isolation layer IL. The lateral direction length of the word lines DWL1 to DWL4 may be the same as the lateral direction length of the cell isolation layers IL. The cell isolation layers IL may be referred to as a lateral-level isolation layer.

A dielectric pad PDIL may be positioned below the word line pad portion WLE of the word line stack WLS. The dielectric pad PDIL may include the dielectric pad PDIL shown in FIGS. 1F and 2F. The dielectric pad PDIL may include a plurality of line pads PAD1, PAD2, and PAD3 and a plurality of auxiliary pads APAD as illustrated in FIGS. 1F and 2F.

As described above, since the word line pads WLP1 to WLP4 are respectively formed between the first pad WE1 and the second pad WE2, the resistance of the word lines DWL1 to DWL4 may be reduced. Also, it is possible to prevent the contact plugs WC1 to WC4 from being punched due to the word line pads WLP1 to WLP4.

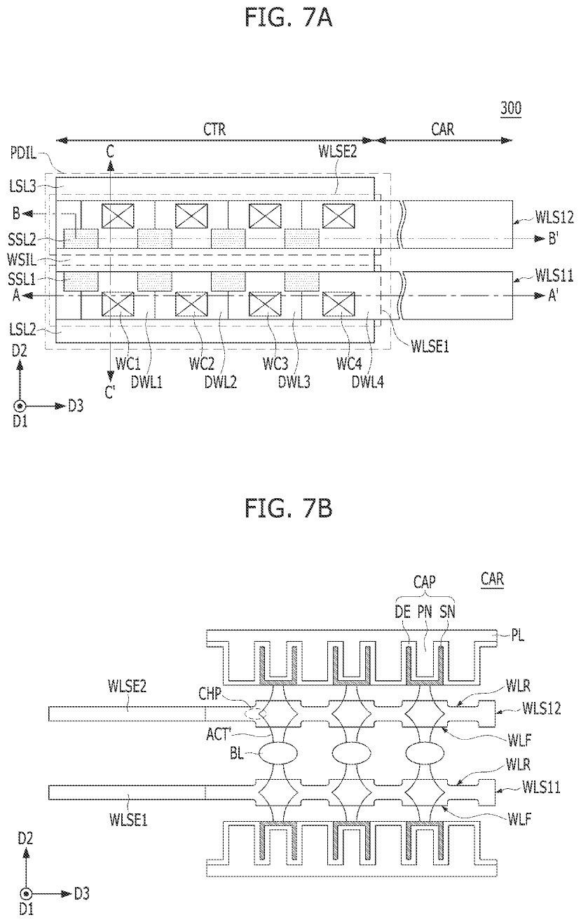

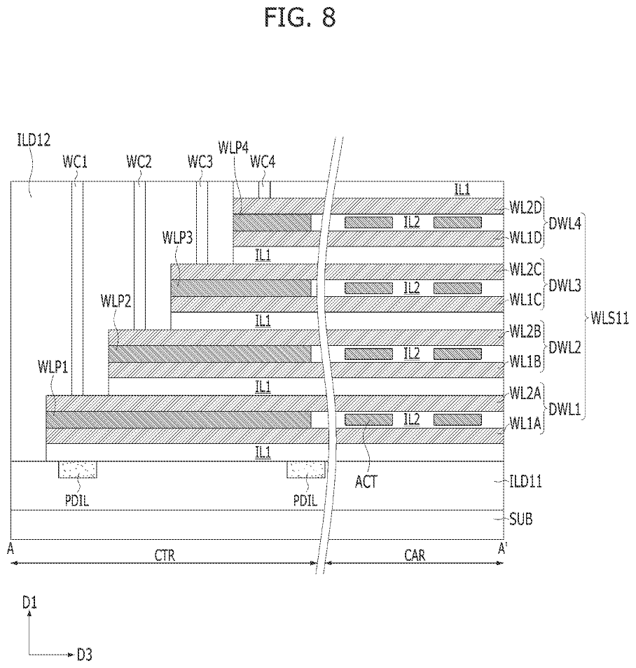

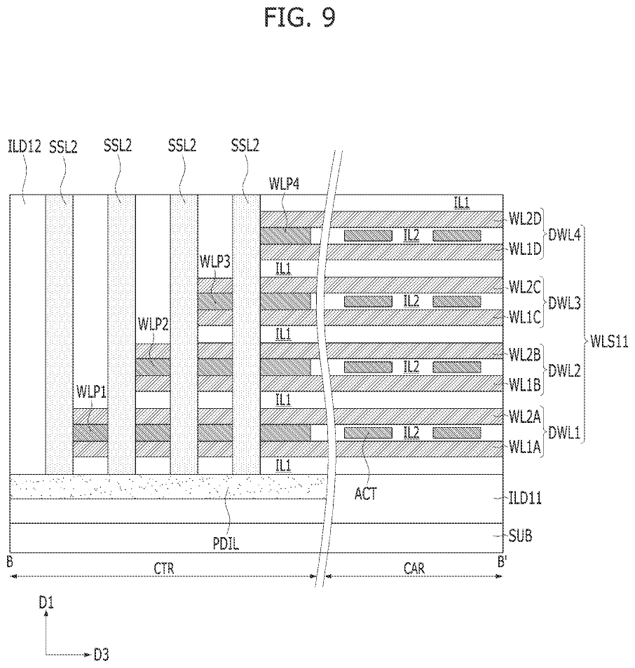

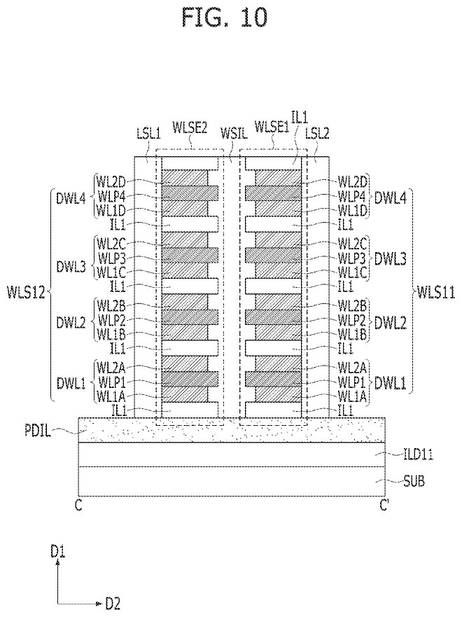

FIG. 7A is a schematic plan view illustrating a semiconductor device in accordance with other embodiments of the present invention. FIG. 7B is a detailed layout view illustrating a cell array portion shown in FIG. 7A. FIG. 8 is a cross-sectional view taken along a line A-A′ shown in FIG. 7A. FIG. 9 is a cross-sectional view taken along a line B-B′ shown in FIG. 7A. FIG. 10 is a cross-sectional view taken along a line C-C′ shown in FIG. 7A. In FIGS. 7A to 10, detailed descriptions on the constituent elements also appearing in FIGS. 3 to 6 will be omitted.

Referring to FIGS. 7A to 10, the semiconductor device 300 may include a cell array portion CAR and a contact portion CTR. The memory cells MC of the memory cell array MCA as shown in FIGS. 5 and 6 may be positioned in the cell array portion CAR, and a word line pad portion WLE of the cell array MCA may be positioned in the contact portion CTR. A plurality of contact plugs WC1 to WC4 may be further positioned in the contact portion CTR. The cell array portion CAR may extend laterally from the contact portion CTR. A dielectric pad PDIL may be positioned below the contact portion CTR.

The semiconductor device 300 may include a plurality of word line stacks WLS11 and WLS12, and each of the word line stacks WLS11 and WLS12 may include a plurality of word lines DWL1 to DWL4. The word lines DWL1 to DWL4 may be vertically stacked in the first direction D1. The word lines DWL1 to DWL4 may extend laterally in the third direction D3. The word lines DWL1 to DWL4 may be formed in the cell array portion CAR and extend to the contact portion CTR. The word lines DWL1 to DWL4 may have a double word line structure of the first word lines WL1A to WL1D and the second word lines WL2A to WL2D. For example, the word line DWL1 may have a double word line structure of the first word line WL1A and the second word line WL2A, and the word line DWL2 may have a double word line structure of the first word line WL1B and the second word line WL2B. The word line DWL3 may have a double word line structure of the first word line WL1C and the second word line WL2C, and the word line DWL4 may have a double word line structure of the first word line WL1D and the second word line WL2D.

The word line stacks WLS11 and WLS12 may include word line stack pad portions WLSE1 and WLSE2, respectively. Each of the word line stack pad portions WLSE1 and WLSE2 may have a step shape, and the step shape may be defined in the contact portion CTR. Each of the word line stack pad portions WLSE1 and WLSE2 may include a stack of word line pad portions WLE1 to WLE4 as illustrated in FIG. 6. A plurality of word line pads WLP1 to WLP4 may be positioned in the contact portion CTR. The word line pads WLP1 to WLP4 may extend laterally in the third direction D3. The lateral lengths of the word line pads WLP1 to WLP4 may gradually decrease as it goes from the lowermost word line pad WLP1 toward the uppermost word line pad WLP4. Contact plugs WC1 to WC4 may be respectively coupled to the word line stack pad portions WLSE1 and WLSE2. According to another embodiment of the present invention, the contact portion CTR may be referred to as a ‘connection region’, and the word line stack pad portions WLSE1 and WLSE2 may be referred to as a stepped connection portions including conductive pad regions. According to another embodiment of the present invention, the contact portion CTR may be referred to as a stepped contact portion. The word line stack pad portions WLSE1 and WLSE2 may be integrated to be coupled to the word line stacks WLS11 and WLS12. A dielectric pad PDIL may be positioned below the word line stack pad portions WLSE1 and WLSE2. The dielectric pad PDIL may include the dielectric pad PDIL shown in FIGS. 1F and 2F. The dielectric pad PDIL may include a plurality of line pads PAD1, PAD2, and PAD3 and a plurality of auxiliary pads APAD as illustrated in FIGS. 1F and 2F.

The semiconductor device 300 may further include large slits LSL1 and LSL2 and an isolation slit WSIL that are disposed in the contact portion CTR, and the large slits LSL1 and LSL2 and the isolation slit WSIL may extend in the third direction D3. In the second direction D2, the word line stacks WLS11 and WLS12 may be positioned between the large slits LSL1 and LSL2, and the isolation slit WSIL may be positioned between the word line stacks WLS11 and WLS12. The isolation pillar WSIL may provide electrical isolation of the word line stacks WLS11 and WLS12.

The large slits LSL1 and LSL2 may include a first large slit LSL1 and a second large slit LSL2. The word line stacks WLS11 and WLS12 may include a first word line stack WLS11 and a second word line stack WLS12. The second word line stack WLS12 may be positioned between the first large slit LSL1 and the isolation slit WSIL, and the first word line stack WLS11 may be positioned between the second large slit LSL2 and the isolation slit WSIL. In other words, the word line stack pad portion WLSE2 of the second word line stack WLS12 may be positioned between the first large slit LSL1 and the isolation slit WSIL, and the word line stack pad portion WLSE1 of the first word line stack WLS11 may be positioned between the second large slit LSL2 and the isolation slit WSIL.

The semiconductor device 300 may further include small slits SSL1 and SSL2 positioned in the contact portion CTR. The small slits SSL1 and SSL2 may extend vertically in the first direction D1 and may contact first sidewalls of the word line stack pad portions WLSE1 and WLSE2, respectively. The small slits SSL1 and SSL2 may pass through first sidewalls of the word line stack pad portions WLSE1 and WLSE2. The first small slits SSL1 may pass through the first sidewall of the word line stack pad portion WLSE1 of the first word line stack WLS11, and the second small slits SSL2 may pass through the first sidewall of the word line stack pad portion WLSE2 of the second word line stack WLS12. The first and second small slits SSL1 and SSL2 may directly contact the isolation slit WSIL.

The word line stack pad portions WLSE1 and WLSE2 and the word line pads WLP1 to WLP4 may be supported by the isolation slit WSIL, the large slits LSL1 and LSL2, and the small slits SSL1 and SSL2. The isolation slit WSIL, the large slits LSL1 and LSL2, and the small slits SSL1 and SSL2 may be referred to as supporters. The isolation slit WSIL, the large slits LSL1 and LSL2, and the small slits SSL1 and SSL2 may be formed of a dielectric material.

Referring back to FIGS. 9 and 10, a dielectric pad PDIL may be positioned below the isolation slit WSIL, the large slits LSL1 and LSL2, and the small slits SSL1 and SSL2. The dielectric pad PDIL may correspond to the dielectric pad PDIL shown in FIGS. 1F and 2F. Referring back to FIGS. 1F and 2F, the dielectric pad PDIL may include a plurality of line pads PAD1 and PAD2 that are parallel to each other and a plurality of auxiliary pads APAD that connect the line pads PAD1 and PAD2 to each other. The line pads PAD1 and PAD2 and the auxiliary pads APAD may be positioned at the same level.

The dielectric pad PDIL may be positioned over the lower structure SUB, and the word line stacks WLS11 and WLS12 may be positioned at a higher level than the dielectric pad PDIL. The word line stacks WLS11 and WLS12 may include first and second word line stack pad portions WLSE1 and WLSE2. A slit structure may be formed to be positioned between the first word line stack pad portion WLSE1 and the second word line stack pad portion WLSE2 and to vertically extend from the dielectric pad PDIL. The slit structure may include the isolation pillar WSIL, the large slits LSL1 and LSL2, and the small slits SSL1 and SSL2.

Referring back to FIG. 10, the isolation slit WSIL may include a plurality of protrusions that directly contact the first and second word lines WL1A to WL1D and WL2A to WL2D. The lateral lengths of the first and second word lines WL1A to WL1D and WL2A to WL2D in the second direction D2 may be smaller than the lateral lengths of the word line pads WLP1 to WLP4 in the second direction D2.

The first and second word line stacks WLS11 and WSL12 may be positioned over the lower structure SUB, and an inter-layer dielectric layer ILD11 may be positioned between the first and second word line stacks WLS11 and WLS12 and the lower structure SUB.

Each of the first and second word line stacks WLS11 and WLS12 may include multi-level word lines DWL1 to DWL4. A first lateral level dielectric layer IL1 may be positioned between the word lines DWL1 to DWL4. In the cell array portion CAR, a plurality of active layers ACT may be positioned between the first word lines WL1A to WL1D and the second word lines WL2A to WL2D. A second lateral level dielectric layer IL2 may be positioned between the active layers ACT in the cell array portion CAR. In the contact portion CTR, word line pads WLP1 to WLP4 may be positioned between the first word lines WL1A to WL1D and the second word lines WL2A to WL2D. Contact plugs WC1 to WC4 may be coupled to the second word lines WL2A to WL2D, respectively. The contact plugs WC1 to WC4 may pass through the second inter-layer dielectric layer ILD12. The second inter-layer dielectric layer ILD12 may cover the word line stack pad portions WLSE1 and WLSE2 of the word line stacks WLS11 and WLS12.

FIG. 7B is a detailed plan view of the cell array portion CAR, which includes first and second word line stacks WLS11 and WLS12, active layers ACT′, bit lines BL, capacitors CAP, and plate lines PL. The bit lines BL may extend vertically in the first direction D1. The active layers ACT′ may extend laterally in the second direction D2. The first and second word line stacks WLS11 and WLS12 may extend laterally in the third direction D3. The cell array portion CAR may have a mirror-type structure in which the bit lines BL are shared. The cell array portion CAR may include vertical bit lines BL positioned between the first word line stack WLS11 and the second word line stack WLS12, active layers ACT′ respectively coupled to the vertical bit lines BL, and capacitors CAP including storage nodes SN respectively coupled to the active layers ACT′, wherein the active layers ACT′ are oriented laterally in the second direction D2, and each of the first and second word line stacks WLS11 and WLS12 may include the word lines DWL1 to DWL4 that extend laterally in the third direction D3 intersecting with the active layers ACT′.

Referring back to FIGS. 7A and 7B, the first and second word line stacks WLS11 and WLS12 in the cell array portion CAR may include a notch-shaped sidewall from the perspective of a plan view. The sidewalls of the word line stack pad portions WLSE1 and WLSE2 of the first and second word line stacks WLS11 and WLS12 extending from the cell array portion CAR may have a linear shape. Each of the word line stacks WLS11 and WLS12 of the cell array portion CAR may include a notch-shaped sidewall extending in the third direction D3 and facing each other. In other words, the word lines DWL1 to DWL4, the first word lines WL1A to WL1D, and the second word lines WL2A to WL2D may also include notch-shaped sidewalls extending in the third direction D3. Each of the notch-shaped sidewalls may include flat surfaces WLF and recessed surfaces WLR. The flat surfaces WLF and the recessed surfaces WLR may be alternately repeated in the third direction D3. The flat surfaces WLF may be flat sidewalls, and the recessed surfaces WLR may be recessed sidewalls.

In the word line stacks WLS11 and WLS12, the distance between the flat surfaces WLF facing each other in the second direction D2 may be greater than the distance between the opposite recessed surfaces WLR facing each other in the second direction D2. According to another embodiment of the present invention, the recessed surfaces WLR may have a round shape. For example, each of the recessed surfaces WLR may have a hemispherical notch shape and may be symmetrical to each other in the second direction D2.

In the contact portion CTR, the sidewalls of the word line stack pad portions WLSE1 and WLSE2 of the first and second word line stacks WLS11 and WLS12 may have a linear shape in which flat surfaces WLF extend in the third direction D3.

The active layer ACT′ may include channel protrusions CHP, and the channel protrusions CHP may vertically overlap with the first and second word line stacks WLS11 and WLS12. The active layer ACT′ may have a rhombus shape.

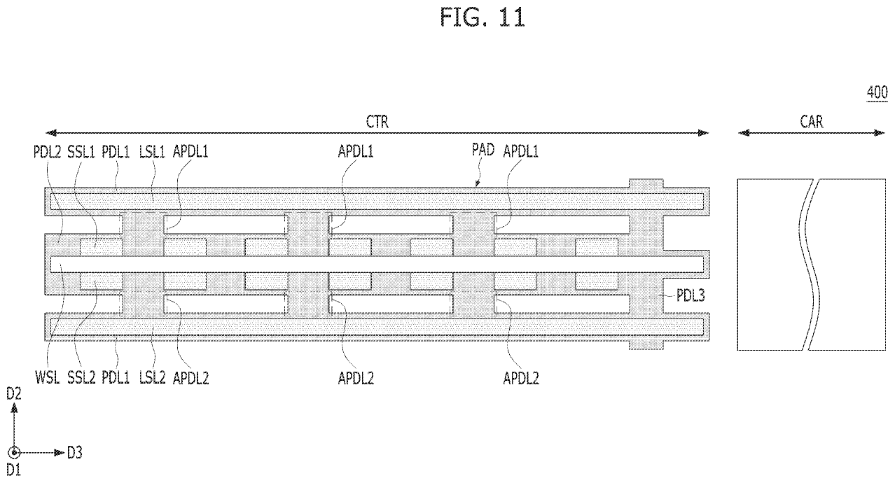

FIG. 11 is a schematic plan view illustrating a sacrificial pad of a semiconductor device in accordance with another embodiment of the present invention.

Referring to FIG. 11, the semiconductor device 400 may include a cell array portion CAR and a contact portion CTR, and a sacrificial pad PAD may be positioned in the contact portion CTR. The sacrificial pad PAD illustrated in FIG. 11 may be similar to the sacrificial pad PAD illustrated in FIGS. 1A and 2A.

Referring to FIGS. 1A, 2A, and 11, the sacrificial pad PAD may have a mesh-shape or a lattice-shape. The sacrificial pad PAD may include a plurality of line portions PDL1, PDL2 and PDL3 and a plurality of auxiliary lines APDL1 and APDL2. The line portions PDL1, PDL2 and PDL3 may include a first line portion PDL1, a second line portion PDL2, and a third line portion PDL3. The auxiliary lines APDL1 and APDL2 may include a first auxiliary line APDL1 and a second auxiliary line APDL2. The first and second line portions PDL1 and PDL2 may extend in the third direction D3, and the third line portion PDL3 may extend in the second direction D2. The second direction D2 and the third direction D3 may intersect with each other. The first and second auxiliary lines APDL1 and APDL2 may be positioned between the first line portion PDL1 and the second line portion PDL2. The first and second auxiliary lines APDL1 and APDL2 may interconnect the first line portion PDL1 and the second line portion PDL2 to each other. The first line portion PDL1, the second line portion PDL2, the third line portion PDL3, the first auxiliary line APDL1, and the second auxiliary line APDL2 may have an integrated structure. The first line portion PDL1, the second line portion PDL2, the third line portion PDL3, and the first and second auxiliary lines APDL1 and APDL2 may be formed of the same material. The first line portion PDL1, the second line portion PDL2, the third line portion PDL3, the first auxiliary line APDL1, and the second auxiliary line APDL2 may be positioned at the same lateral level.

According to an embodiment of the present invention, a plurality of the first auxiliary lines APDL1 may be positioned between the first line portion PDL1 and the second line portion PDL2 in the third direction D3. A plurality of the second auxiliary lines APDL2 may also be positioned between the first line portion PDL1 and the second line portion PDL2 in the third direction D3. For example, the first auxiliary lines APDL1 may be positioned between two small slits SSL1, and the second auxiliary lines APDL2 may be positioned between two small slits SSL2.

Large slits LSL1 and LSL2 may be positioned over the first line portions PAD1, and a plurality of the small slits SSL1 and SSL2 may be positioned over the second line portions PAD2. An isolation trench WSL may be positioned between the small slits SSL1 and SSL2 that are adjacent in the second direction D2, and the isolation trench WSL may extend in the third direction D3.

A series of the processes as illustrated in FIGS. 1B to 1F and 2B to 2F may be performed using the sacrificial pad PAD which is described with reference to FIG. 11. For example, the sacrificial pad PAD shown in FIG. 11 may be used as an etch stopper in an etching process for forming the openings L1, L2, SL1, and SL2 of FIG. 1B. Also, the sacrificial pad PAD shown in FIG. 11 may be used as an etch stopper in an etching process for forming the isolation trench WSL shown in FIG. 1D.

Since the sacrificial pad PAD shown in FIG. 11 may include a plurality of the first and second auxiliary lines APDL1 and APDL2, a path for stripping the sacrificial pad PAD as illustrated in FIG. 1E may be increased. Therefore, the sacrificial pad PAD may be removed more easily without any residue.

The operations of forming the bit line BL, the word line DWL, and the word line stack WLS of the memory cell array MCA including memory cells MC according to FIGS. 3 to 10 may include a process of etching an etch target layer. Herein, the etch target layer may include the etch target layer ET as illustrated in FIGS. 1A to 2F, and the etch target layer ET may be an alternating stack in which an oxide layer, a first nitride layer, a semiconductor layer, and a second nitride layer are repeatedly stacked several times in the mentioned order. The process of etching the alternating stack may use the sacrificial pad PAD shown in FIG. 1A or FIG. 11 as the etch stopper. The etching process for forming the bit line BL, the word line DWL, and the word line stack WLS may include etching the alternating stack to form an isolation trench, forming an isolation structure filling the isolation trench, etching the alternating stack to form a first vertical opening, replacing a portion of the first nitride layer and the second nitride layer of the alternating stack with the word lines DWL through the first vertical opening, forming a bit line BL filling the first vertical opening, etching the alternating stack to form a second vertical opening, recessing the first nitride layer, the semiconductor layer, and the second nitride layer of the alternating stack through the second vertical opening to form a capacitor opening, and forming a capacitor CAP in the capacitor opening. The sacrificial pad PAD may be used as an etch stopper in the etching process of the alternating stack for forming the isolation trench, the first vertical opening, and the second vertical opening.

According to an embodiment of the present invention, since a sacrificial pad of a metal-based material is formed below an etch target layer, it is possible to prevent arcing during an etch process of the etch target layer, thereby improving the reliability of the semiconductor device.

According to an embodiment of the present invention, since a sacrificial pad of a metal-based material is formed below an etch target layer, it is possible to discharge the charges that are induced during a plasma etching process of the etch target layer toward an underlying structure.

According to an embodiment of the present invention, since the sacrificial pad includes a plurality of auxiliary lines to provide a path for wet chemicals, it is possible to easily remove the sacrificial pad without residues.

While the present invention has been described with respect to specific embodiments, it will be apparent to those skilled in the art that various changes and modifications may be made without departing from the spirit and scope of the invention as defined in the following claims.

What is claimed is:

1. A semiconductor device comprising:
a dielectric pad over a lower structure;
a contact portion positioned at a higher level than the dielectric pad, the contact portion including a first word line stack pad and a second word line stack pad; and
a slit structure including a plurality of slits extending vertically from the dielectric pad to support the first word line stack pad and the second word line stack pad.

2. The semiconductor device of claim 1, wherein the dielectric pad includes:
a plurality of line pads that are parallel to each other; and
a plurality of auxiliary pads coupling the line pads to each other.

3. The semiconductor device of claim 2, wherein the line pads and the auxiliary pads are positioned at the same level.

4. The semiconductor device of claim 1,
wherein each of the first word line stack pad and the second word line stack pad includes a plurality of word line pads that are stacked in a direction perpendicular to a surface of the dielectric pad, and
wherein the stack of the word line pads has a step-type structure.

5. The semiconductor device of claim 4, wherein each of the word line pads include:
a first pad and a second pad that are stacked in a direction perpendicular to the surface of the dielectric pad; and
a word line pad interposed between the first pad and the second pad.

6. The semiconductor device of claim 1, further comprising:
a cell array portion extending laterally from the contact portion and including a first word line stack and a second word line stack,
wherein the first word line pad is defined at end portions of the first word line stack, and
the second word line pad is defined at end portions of the second word line stack.

7. The semiconductor device of claim 6, wherein the cell array portion includes:
vertical bit lines disposed between the first word line stack and the second word line stack;
active layers respectively coupled to the vertical bit lines; and
capacitors including storage nodes that are respectively coupled to the active layers,
wherein the active layers are oriented laterally between the vertical bit lines and the capacitors, and
wherein each of the first and second word line stacks includes word lines extending laterally in a direction crossing the active layers.

8. A method for fabricating a semiconductor device, comprising:
forming a sacrificial pad including a plurality of line portions and a plurality of auxiliary lines over a lower structure;
forming an etch target layer over the sacrificial pad;
forming a plurality of openings by etching the etch-target layer and stopping the etching at the sacrificial pad;
forming a slit filling the openings;
forming an isolation trench by etching the etch-target layer and stopping the etching at the sacrificial pad; and
forming a pad-type recess by removing the sacrificial pad through the isolation trench.

9. The method of claim 8, wherein the sacrificial pad includes a material having an etch selectivity with respect to the etch target layer.

10. The method of claim 8, wherein the sacrificial pad includes a metal-based material.

11. The method of claim 8, wherein the etch target layer includes an alternating stack in which different materials are alternately stacked, and
the sacrificial pad has an etch selectivity with respect to the alternating stack.

12. The method of claim 8, wherein the etch target layer includes
a dielectric layer, a semiconductor layer, or a combination thereof.

13. The method of claim 8, wherein the etch target layer includes
an alternating stack in which dielectric layers and semiconductor layers are alternately stacked.

14. The method of claim 8, wherein the etch target layer includes
at least one stacked layer where a first dielectric layer, a second dielectric layer, a semiconductor layer, and a third dielectric layer are stacked in a mentioned order,
wherein the first dielectric layer includes silicon oxide,
wherein the second and third dielectric layers include silicon nitride, and
wherein the semiconductor layer includes polysilicon.

15. The method of claim 8, wherein the etch target layer includes an alternating stack in which first semiconductor layers and second semiconductor layers are alternately stacked,
wherein the first semiconductor layers include monocrystalline silicon or polysilicon, and
wherein the second semiconductor layers include silicon germanium.

16. The method of claim 8, wherein the sacrificial pad includes titanium nitride, tungsten, or a combination thereof.
